(19) United States
(12) Patent Application Publication
(10) Pub. No.: US 2010/0162957 A1
(43) Pub. Date: Jul. 1, 2010

(54) DEVICE FOR COATING A PLURALITY OF CLOSEST PACKED SUBSTRATES ARRANGED ON A SUSCEPTOR

(76) Inventors: Adam Boyd, Kelmis (BE); Victor Saywell, Suffolk (GB); Jan Mulder, Eindhoven (NL); Olivier Feron, Hsinchu (TW); Johannes Käppeler, Wurselen (DE)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(21) Appl. No.: 12/601,234

(22) PCT Filed: May 21, 2008
(86) PCT No.: PCT/EP08/56268

§ 371 Date: Nov. 20, 2009

(30) Foreign Application Priority Data
May 23, 2007 (DE) 10 2007 023 970.1

(51) Int. Cl. C23C 16/46; C23C 16/458

(52) U.S. Cl. 118/725; 118/500

(57) ABSTRACT

The invention relates to a device for coating a plurality of substrates (3) which are regularly arranged on a bearing surface (2) of a susceptor (1) associated to a process chamber (14), wherein the bearing surface (2) forms abutment flanks (5) for the edge mounting of each substrate (3). In order to reduce the free susceptor surface to a minimum, it is proposed that the abutment flanks of the lateral walls (5) are formed by bases (4) which project from the bearing surface (2) and are separated at a distance from one another. Said bases are arranged on the corner points (10) of a honeycomb structure and have an outline essentially corresponding to an equilateral triangle with inwardly curved sides (5).

The invention relates to a device for coating a plurality of substrates arranged in a regular manner on a support surface of a susceptor associated with a process chamber, the support surface providing abutment flanks for edge engagement of each substrate.

U.S. Pat. No. 5,814,196 describes a coating device in which the substrates sit in recesses, the edges of the recesses matching the peripheral shape of the substrates. The floors of the recesses define support surfaces for the substrates. The centers of the substrates are located at the corner points of equilateral triangles.

A device for polishing substrates is known from US 2003/0109139 A1, in which each of three substrates lie on substrate carriers in a planetary type arrangement.

DE 10 2004 009 130 A1 describes a device for coating a multiplicity of substrates arranged in a regular manner on a support surface of a susceptor associated with a process chamber, the support surface providing abutment flanks for edge engagement of each substrate. The substrates are in this case disposed on a total of six rotatable disks. The rotatable disks are disposed in a hexagonal arrangement about the center of a susceptor.

A similar arrangement is shown by DE 100 43 600 A1.

In the known devices for coating a multiplicity of substrates, the substrates are in a circular arrangement about the center of a susceptor. In a first row, four substrates lie, for example, uniformly distributed about the center of the susceptor. The substrates thus sit in individual recesses in the upper surface of the susceptor, the centers of the individual recesses running on a circular line around the center. In a second circle around the center, ten substrates lie, likewise each in an individual recess. In a third circle about the center, sixteen substrates lie in corresponding manner in individual recesses, the centers of which have the same spacing from the center of the susceptor.

An arrangement of this kind of substrates on a susceptor brings certain advantages. The process chamber is located above the support surface of the susceptor, into which chamber process gases are conducted from above by way of a gas inlet member. These process gases react either in the gas phase or on the upper surfaces of the substrates to be coated, elements of the process gases being deposited on the substrates during formation of a layer. For this, the susceptor is usually heated from underneath.

It is basically unavoidable that parasitical growth takes place in the interspaces of the susceptor between the individual recesses. The parasitic growth results not only in an undesirable depletion of the gas phase, but also has a negative effect on the homogeneity of the deposited layers.

It is therefore an object of the invention to improve the known device advantageously in regard to its usability.

This object is met by the invention specified in the claims, each claim representing an independent solution to the problem and being combinable with any other claim.

The solution procedure followed by the invention provides minimisation of the free susceptor upper surfaces between the substrates. To this end, it is first of all proposed that the abutment flanks, against which the edges of the substrate engage, are defined by the side walls of upstanding portions that extend from the support surface. For this, it is advantageous for the upstands to be located at the corner points of a honeycomb-shaped pattern. The upstands may be spaced apart from one another in such a way that edge portions of neighbouring substrates are in contact or almost in contact. In a preferred configuration, the peripheral edges of the upstands follow the peripheral edges of the substrates. Since the substrates are as a rule formed to be substantially circular in shape, the side walls of the upstands have inwardly curved sides. The corner points of the upstand that result from this lie at the corner points of an equilateral triangle, so that the plan view of the upstand substantially corresponds to that of an equilateral triangle with inwardly curved sides. The upstands preferably rise up from the bottom of a depression in the broad side of the substrate holder that faces the process chamber. It is further advantageous for the upstands to be made from a material other than the material of the susceptor. The susceptor is usually made from graphite or a metal. It may however also be made from quartz. The upstands may in this case be formed as insert parts, which are inserted into insert openings in the support surface. Especially preferably, the upstands consist of the same material as that of which the substrates disposed between the upstands also consist, thus of sapphire or of a semi-conductor material. The physical and chemical properties of the upper surfaces of the upstands then correspond to the chemical and physical properties of the upper surfaces of the substrates. The height of the upstands corresponds substantially to the thickness of the material of the substrates. Since the peripheral edges of the substrates are in almost touching engagement against the curved side walls of the upstands, the result is that only a very small fraction of the upper surface of the susceptor, when loaded with substrates, does not have the physical and chemical properties of the substrate. As a result of this configuration, the homogeneity of the layer can be increased. In a development of the invention, it is provided that, as in the state of the art, the substrates also sit in individual recesses that are individually associated with the substrates. It is however here pertinent that the centers of the individual recesses lie at the corner points of a lattice consisting of equilateral triangles. The lattice constant, thus the spacing of the corner points from one another, is therefore only slightly greater than the diameter of the substrates. Here also, the individual recesses define abutment surfaces for the edges of the substrates, the abutment surfaces running on an arcuate line. In the center between the corner points of each triangle, there is a substantially triangular upstanding portion with inwardly curved side walls. The side walls do not however intersect at corners of the upstand, but merge into a neighbouring upstand, a material bridge being formed. In this solution also, the free upper surface of the susceptor that is not covered by substrates is minimised.

Exemplary embodiments of the invention are explained below with reference to accompanying drawings, in which:

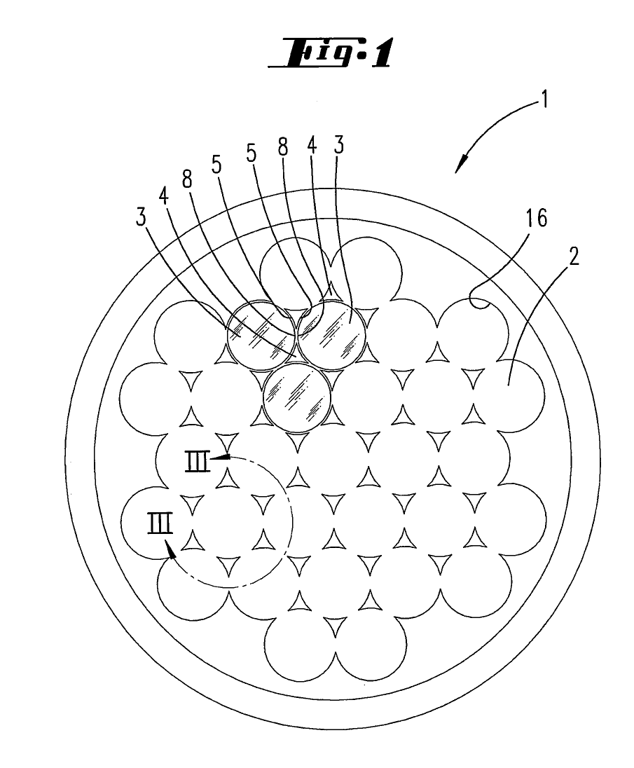

FIG. 1 shows the plan view on to the support surface of a susceptor of a first exemplary embodiment, which is, for demonstration purposes, only partly loaded with substrates 3;

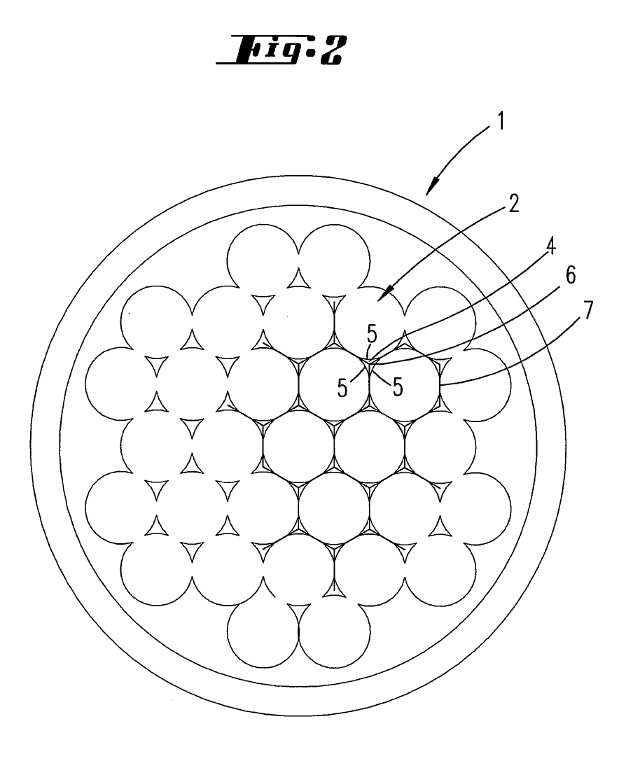

FIG. 2 is an illustration according to claim 1, the center points of triangular upstanding portions 4 being connected to one another by auxiliary lines 7 in order for a honeycomb-shaped pattern to be illustrated;

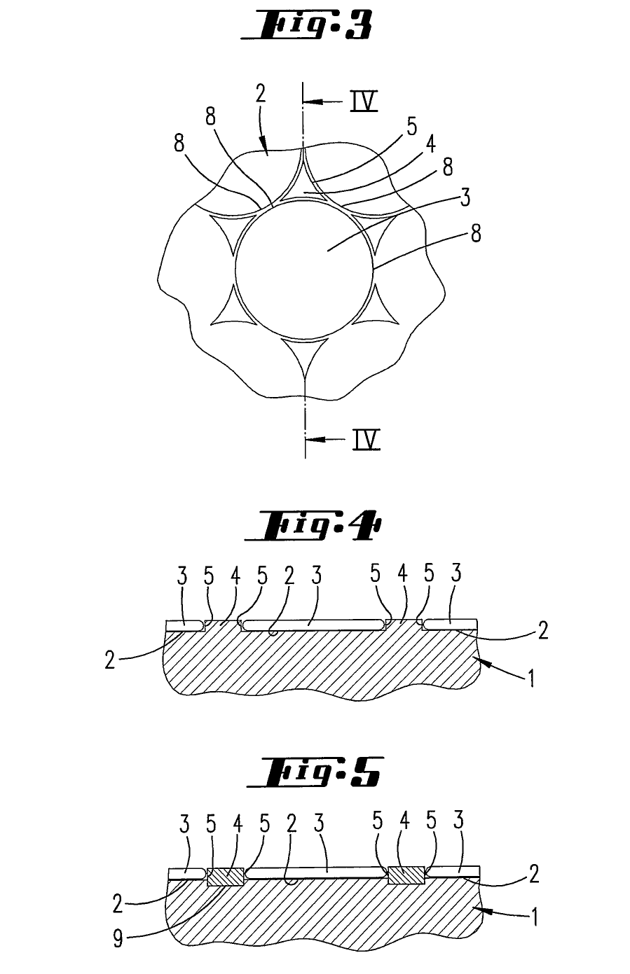

FIG. 3 shows the enlarged extract according to III in FIG. 1;

FIG. 4 shows a section on the line IV-IV in FIG. 3;

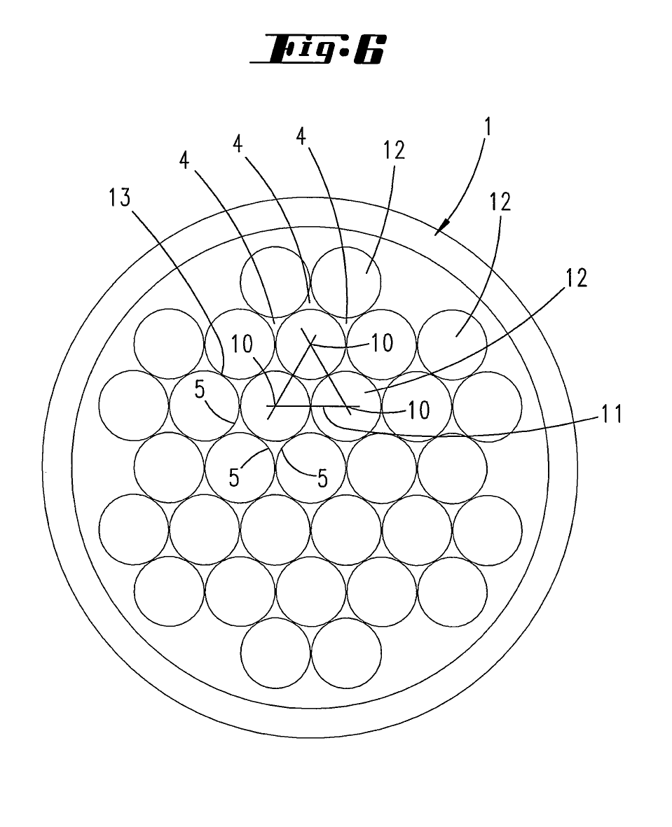

FIG. 5 shows an illustration according to FIG. 4, for a second exemplary embodiment;

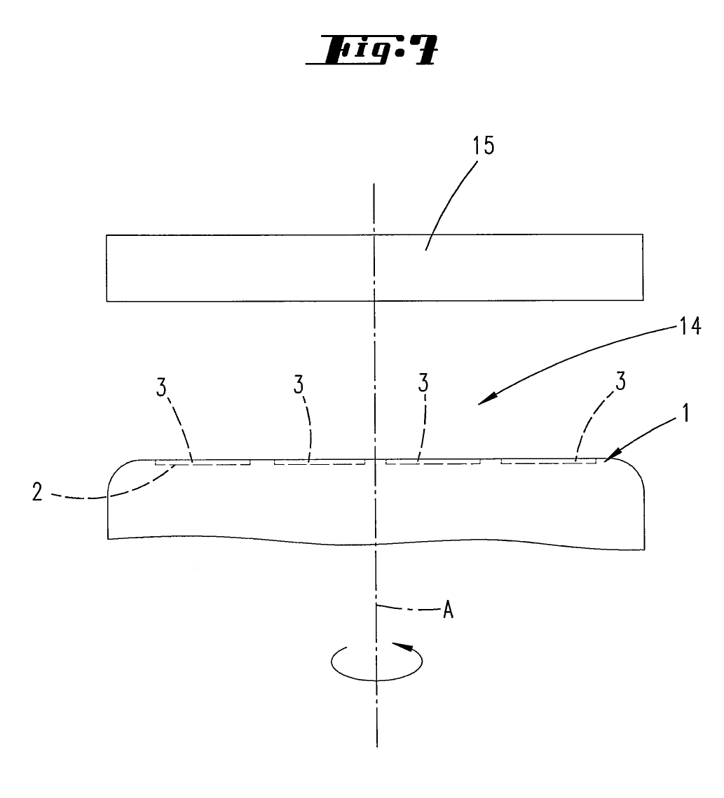

FIG. 6 shows an illustration according to FIG. 1, for a third exemplary embodiment, and

FIG. 7 shows, in schematic illustration, pertinent details of the device according to the invention, for explanation of the invention.

FIG. 7 depicts the interior of a reactor housing of a device for coating a multiplicity of substrates 3 disposed on a susceptor 1. The susceptor consists substantially of a graphite body having a circular upper surface lying in a horizontal plane, the upper surface forming a support surface 2 for a multiplicity of substrates. This susceptor 1, having a diameter of up to 40 cm, can be rotated about an axis of rotation A.

Above the susceptor 1, there is the process chamber 14 which is delimited upwardly by the underside of a gas inlet member 15. By way of openings that are not illustrated and can be distributed in the manner of a shower head over the entire downwardly-facing gas exit face of the gas inlet member 15, one or more process gases enter the process chamber 14, in order there to react on the upper surface of the substrates, either of their own volition in the gas phase or thermally activated by a heater located underneath the susceptor 1. The process gases contain elements of the fourth main group or elements of the third and fifth main groups or elements of the second and sixth main groups. Chlorides, hydrides or metal-organic compounds may be introduced into the process chamber 14 by the gas inlet member, which may also be otherwise configured. The above-mentioned elements of the second to sixth main groups condense with formation of an, in particular, crystalline layer on the upper surface of the substrates 3 that are arranged in a regular manner on the susceptor 1. In order to optimise the growth of the layers on the substrates 3, the substrates are, according to the invention, in the closest possible packing arrangement on the susceptor. A hexagonal arrangement of the substrates is selected. As can be gathered in particular from FIGS. 2 and 6, the centers 10 of the substrates 3 are at the corner points of a lattice in which each lattice cell consists of an equilateral triangle. In FIG. 6, a lattice of this kind is indicated by the auxiliary lines 11, which connect the centers 10 of individual recesses 12 to one another and into which recesses in each case a substrate 3 can be introduced. In FIG. 2, this structure is shown as a honeycomb pattern. As a result of the hexagonal arrangement of the substrates 3 on the susceptor 1, the free surface of the susceptor 1 that is not covered by substrates is minimised.

For the first exemplary embodiment illustrated in FIGS. 1 to 4, the upper side of the susceptor 1, which surface is in a horizontal plane and faces upwards, has a single large recess, this being formed by the support surface 2. The outer edge of the support surface 2 thus follows portions of the edges of substrates located in the recess, the edges running on an arcuate line, with formation of a recess edge 16.

Within the support surface 2, there are upstanding portions 4 extending from the base of this recess that forms the support surface 2. As made clear by the auxiliary lines 7 marked in FIG. 2, the center points 6 of the upstands are located at the lattice points of a hexagonal lattice, in particular of honeycomb shape. In each of these lattice cells, there is a substrate 3. The corner points of the upstands 4 lie at the apices of an equilateral triangle, the side walls 5 of the upstands 4 running on inwardly curved lines. The side walls 5 of the upstands 4 form abutment flanks 5 for the edges 8 of the substrates 3 that are located in each case between six upstands.

Between the corners that face one another of two neighbouring upstands 3, there is a free space, into which portions 8 of the peripheral edge of the substrates 3 can extend in such a manner that the peripheral edges 8 of two neighbouring substrates can touch or are spaced from one another by only a few 100ths of a millimetre. The free surface on the upper surface of the susceptor 1 is formed, as a result of this configuration, by the gusset-shaped upper surfaces of the upstands 4. The spacing of the upstands 4 from one another corresponds to approximately the extent in width of the upstands 4. In FIGS. 1 and 2, the substrates 3 are located centrally in the receiving areas disposed between six upstands. In an eccentric position, portions of the edges 8 of the connecting line between the corner points of the corners of two neighbouring upstands 4 can cross.

As is to be gathered from FIG. 4, in the case of the first exemplary embodiment, the upstands 4 are connected to the susceptor 1 as integral parts of the susceptor. The susceptor may be of graphite, coated graphite, a metal or quartz. The upstands 4 are thus elevations of the support surface 2, on which elevated regions the substrates 3 are arranged. The height of the upstands 4 corresponds substantially to the material thickness of the substrates 3.

FIG. 5 shows a second exemplary embodiment, in which the upstands 4 have a shape in plan view as depicted in FIGS. 1 to 3. In this exemplary embodiment, the upstands 4 are however defined by insertion pieces, which may be formed from a material other than that of the susceptor 1. The insertion pieces forming the upstands 4 are inserted into insertion openings 9 in the support surface 2. Here also, the upstands 4 extend above the support surface 2 by the material thickness of the substrate 3. In the case of this exemplary embodiment, the upstands 4 may consist of the same material as that of which the substrates 3 consist. The upper surface of the susceptor within the edge 16 of the recess is in this exemplary embodiment formed almost exclusively by the upper surfaces of the upstands and the upper surfaces of the substrates, which have identical chemical and physical chemistry properties. In this way, it is possible to increase the homogeneity of the deposited layers.

In the third exemplary embodiment illustrated in FIG. 6, the substrates 3 are located in individual recesses 12. The centers 10 of the individual recesses 12 are located here, as described above, at the corner points of a lattice, the lattice cell of which has the shape of an equilateral triangle. The length of the side of the triangle is only slightly greater than the diameter of the substrates 3 or the diameter of the individual recess 12. Here also, there are in each case, neighbouring an upstand 4, three individual recesses which neighbour one another. Two neighbouring upstanding portions 4 are however connected to one another in this exemplary embodiment, a material bridge being formed. The material bridge 13 forms a constriction. The minimum horizontal width of the constriction, thus the minimum width of the material bridge 13, corresponds substantially to the material thickness of the substrate 3 or to the height of the engagement flank 4 which surrounds a substrate 3 continuously.

All features disclosed are (in themselves) pertinent to the invention. The disclosure content of the associated/attached priority documents (copy of the prior application) is hereby also included in full in the disclosure of the application, also for the purpose of incorporating features of these documents in claims of the present application.

1. A device for coating a plurality of substrates (3) that are arranged in a regular manner on a support surface (2) of a susceptor (1) associated with a process chamber (14), the support surface (2) forming abutment flanks for edge engagement of each substrate (3), characterised in that the abutment flanks are defined by side walls (5) of upstands (4) that extend from the support surface (2) and are separated from one another at a spacing, the upstands being located at corner points (10) of a honeycomb-shaped pattern and having a shape in plan view that substantially corresponds to an equilateral triangle with inwardly curved sides.

2. A device according to claim 1, characterised in that the upstands (4) are spaced apart from one another in such a way that edge portions (8) of neighbouring substrates (3) are in contact or almost in contact with one another.

3. A device according to claim 1, characterised in that the upstands (4) are insertion pieces located in insertion openings (9) in the support surface (2).

4. A device according to claim 3, characterised in that the insertion pieces consist of a common material as that from which the substrates (3) consist, in particular sapphire or another semi-conductor material.

5. A device according to claim 1, characterised in that the susceptor (1) consists of one of graphite or a metal or quartz.

6. A device according to claim 1, characterized in that the abutment flanks have a height which corresponds substantially to a thickness of the substrates (3).

7. A device according to claim 1, characterized in that the process chamber (14) is disposed above the susceptor (1), and is delimited upwardly by an underside of a gas inlet member (15), the gas inlet member having downwardly-facing openings which are distributed in the manner of a shower head over an entire downwardly-facing gas exit surface of the gas inlet member (15), and from which openings, one or more process gases enter the process chamber (14), in order thereto react on upper surfaces of the substrates either of their volition in the gas phase or thermally activated by a heater located underneath the susceptor (1).
